(19) United States
(12) Patent Application Publication
(10) Pub. No.: US 2005/0270736 A1
(43) Pub. Date: Dec. 8, 2005

(54) Electronic equipment and method for use the electronic equipment

(75) Inventors: Esa Maatta, Viiala (FI); Timo Herranen, Viiala (FI)

Correspondence Address: HARRINGTON & SMITH, LLP, 4 RESEARCH DRIVE, SHELTON, CT, 06484-6212, US

(73) Assignee: Nokia Corporation

(21) Appl. No.: 11/144,582

(22) Filed: Jun. 2, 2005

(30) Foreign Application Priority Data
Jun. 4, 2004 (FI) 20045210

(51) Int. Cl. H05K 5/00; G06F 1/16

(52) U.S. Cl. 361/683

(57) ABSTRACT

The invention concerns electronic equipment including a body structure in which a place is arranged for at least one display and belonging in connection with the body structure display means including at least one said display, whereby the said display allows use of the equipment in at least two operating modes, and user interface means for inputting information to the equipment and including at least one input part being constantly on view, and which equipment and especially its at least one said display can be adapted to at least two operating modes for presenting the information, of which in the first operating mode, being the mobile-station operating mode, the said display is adapted to merge with the body structure of the equipment being in the place arranged for it, and in the second operating mode, the display is raised from its place, and in both operating modes information is adapted to be inputted to the equipment by the user interface means. The second operating mode is a desktop operating mode in which the viewing angle (α) of the display is adapted for the desktop use of the equipment.

### FIELD OF THE INVENTION

The invention concerns electronic equipment including
a body structure in which a place is arranged for at least one display and belonging in connection with the body structure
display means including at least one said display, whereby the said display allows use of the equipment in at least two operating modes, and
user interface means for inputting information to the equipment and including at least one input part being constantly on view, and
   which equipment and especially its at least one said display can be adapted to at least two operating modes for presenting the information, of which
in the first operating mode, being the mobile-station operating mode, the said display is adapted to merge with the body structure of the equipment being in the place arranged for it, and
in the second operating mode, the display is raised from its place,
   and in both operating modes information is adapted to be inputted to the equipment by the user interface means. In addition, the invention also concerns a method for use the electronic equipment and a body structure for the electronic equipment.

### BACKGROUND OF THE INVENTION

Portable electronic equipment on the market today are mainly for carrying in the hand, which means that they do not provide in any user-friendly way for, for example, using multimedia services of different kinds or the desktop use. Some although in no way limiting examples of such services are, for example, watching digital television broadcasts, carrying out video/telephone negotiations simultaneously while writing a memo, watching movies, internet browsing, for example, by using a wireless mouse and/or a keyboard or listening to the radio.

Holding the equipment in one's hand over longer periods of time is in no way a pleasant experience from the user's point of view. In fact, it would often be nicer to use the equipment, for example, on a table in a manner like portable computers or other desktop devices. However, the structural architecture of present day hand-held equipment is not intended for use on a desktop.

Furthermore, in the known electronic equipment there are separate display elements for a limited mobile-station operating mode and for an enlarged desktop operating mode respectively. In many cases, these are located on different sides of the equipment, which means they are also showing in different directions. A display for use in a mobile-station operating mode need not necessarily have so large a size as a multimedia display used for watching multimedia or performing, for example, processing of information. The body structure of such equipment is mainly formed of many blocks, of which implementations of the clamshell type can be mentioned as an example. The Nokia Communicator equipment may be mentioned as another example of such a multi-block implementation.

In the equipment mentioned above, the display part or the body block including it is arranged in the equipment in a fixed and articulated manner, whereby in structural terms it forms a complex solution. In addition, another drawback of equipment having several display parts is the thickness of the body of such equipment, whereas the body should preferably be as thin as possible in portable handset equipment.

Furthermore, besides the said drawbacks, known electronic equipment have no stereo hands-free features, for example. With known equipment it is not possible to share the stereo sound between several users, because the equipment has only one connection for the earphone-microphone combination.

One example that represents the prior art in the handset devices is described in U.S. Pat. No. 6,539,208 B1. That describes a solution in which the device has two operating modes. These are provided in order to expand the area of the display unit and also increase the number of key buttons. However, these two operating modes are both pure mobile-station modes. In first mode the device may be operated using limited key button portion. In that mode the display is in its place arranged in the body of the device. In second mode the device may be operated using extended key button portion. In this mode the display unit is raised away from its body place. The presented solution provides wider display element in connection with mobile phone. However, the display's mechanical hinge shaft structure, by means of which the display is connected to the body part of the device, doesn't allow the desktop operating mode. The structure has also such a drawback that when adapting the device to the expanded operating mode its length increases considerably. One more drawback is the movement of the display unit when changing operating mode. This may form usability problem because the movement made by the user is quite complex.

### SUMMARY OF THE INVENTION

It is a purpose of the present invention to bring about electronic equipment of a new kind and a method for use the electronic equipment in different operating modes. The characteristic features of the electronic equipment according to the invention are presented in the appended claim 1 and those of the corresponding method are presented in claim 11. In addition, the invention also concerns a body structure, whose characteristic features are presented in the appended claim 16.

In particular, the invention concerns usability of portable electronic equipment.

The electronic equipment according to the invention includes a body structure in which a place is arranged for at least one display and belonging in connection with the body structure display means including at least one said display, whereby the said display allows use of the equipment in at least two operating modes, and user interface means for inputting information to the equipment and including at least one input part being constantly on view, and which equipment and especially its at least one said display can be adapted to at least two operating modes for presenting the information, of which in the first operating mode, being the mobile-station operating mode, the said display is adapted to merge with the body structure of the equipment being in the place arranged for it, and in the second operating mode, the display is raised from its place, and in both operating modes information is adapted to be inputted to the equipment by the user interface means. The second operating mode of the equipment is a desktop operating mode in which the viewing angle of the display is adapted for the desktop use of the equipment.

Furthermore, the invention concerns also the method for using electronic equipment. The electronic equipment is formed by a body structure including display means and user interface means in which body structure is arranged a place for at least one display. The display means include at least one said display and the user interface means include at least one input part being constantly on view, and which equipment and especially its at least one said display can be arrange at least two operating mode, in which in the first operating mode being a mobile-station operating mode, the said display merges with the body structure of the equipment being in the place arranged for it, and in the second operating mode, the said display is raised from its place, and in both operating modes information is adapted to be inputted to the equipment by the user interface means and information is presented on the said display. The second operating mode is a desktop operating mode in which the viewing angle of the display may be adapted for the desktop use of the equipment.

Furthermore, the invention relates also to the body structure that is intended to be used in the electronic equipment according to the invention. The following can be fitted in connection with the body structure. The display means, including at least one display for which a place is arranged in the body structure, and user interface means, including at least one input part being constantly on view. At least one said display can be adapted into at least two operating modes for presenting the information, of which in the first operating mode, being the mobile-station operating mode, the said display is adapted to merge into the body structure being in the place arranged for it, and in the second operating mode, the said display is raised from its place. In both operating modes information is adapted to be inputted to the equipment by the user interface means. In the body structure elements are fitted to allow use of the said display in both operating modes to present information. The second operating mode is a desktop operating mode for which elements are fitted to the body structure in order to allow use of the said display in the said desktop operating mode.

According to the method of the invention, the body structure of the electronic equipment according to the invention may be arranged essentially as a mono block solution. In this way, a special advantage is achieved in regard to the size factors of the equipment.

According to a first embodiment, it is possible in the body structure under the display to arrange user interface expansions, which are needed in desktop use in particular, such as, for example, input and/or output means. These may include, for example, a keyboard expansion or loudspeaker devices.

According to another embodiment, the body structure of the equipment may be arranged in such a way that the equipment can be used, for example, in handsfree use. Hereby the display is still well perceptible, even if the equipment is not held in the hand.

According to one more embodiment, the equipment may also be used with wireless user interface means.

The equipment according to the invention combines the advantages of portable and desk equipment in a surprising manner. For implementation of the equipment only one display part is now needed, which may be of the same size in both operating modes. The equipment can hereby be made thinner than present-day equipment with several display parts (for example, Nokia Communicator). The single-display feature also simplifies the technical implementation of the equipment, both at the electronic and also at the physical level. The movement control of the display when changing between operating modes is performed very controlled manner. This caused by the fitting of the hinge parts to the body and to the display. This is important when considering the usability of these kinds of devices.

Other features characteristic of the equipment, method and body structure according to the invention emerge from the appended claims, and more advantages which can be achieved are listed in the specification part.

### BRIEF DESCRIPTION OF THE DRAWINGS

In the following, the invention, which is not limited to the embodiments to be presented hereinafter, will be described in greater detail by referring to the appended figures, wherein

FIG. 1 shows an example of the electronic equipment according to the invention in the mobile-station operating mode,

FIG. 2 shows the equipment according to FIG. 1 in the desktop operating mode,

FIGS. 3a and 3b show an application example of the placing of components in equipment according to the invention as the equipment is in its mobile-station operating mode,

FIGS. 4a and 4b show an application example of the placing of components in equipment according to the invention as the equipment is in its desktop operating mode,

FIG. 5 shows another example of the equipment according to FIG. 1 in the desktop operating mode and

FIGS. 6a-6c show third example of the equipment mechanics in different operating modes and when changing operating mode.

### DETAILED DESCRIPTION OF THE INVENTION

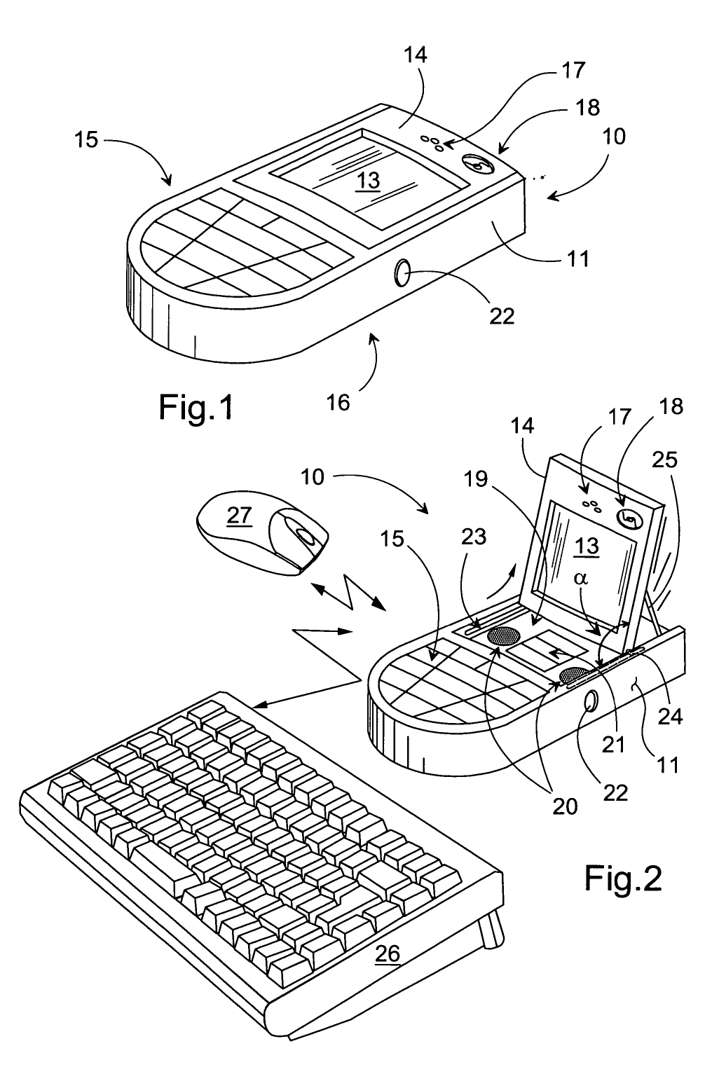

FIGS. 1 and 2 show an example of the electronic equipment 10 according to the invention, which combines in a surprising manner the mobile-station functionality and the multimedia/handsfree properties of desktop equipment. Hereinafter, the electronic equipment 10 according to the invention will be called by the name of desktop or multimedia equipment, because it has the necessary characteristics for presenting multimedia, such as, for example, image/video information and possibly also sound. However, in this context the name of multimedia or equipment is not to be regarded as limiting in any way.

The equipment 10 includes a body structure 11, which inside it contains the electronics of the equipment 10. In addition, the body structure 11, which surprisingly for combined mobile and desktop equipment may have a mono block structure, includes display means 13 and as user interface means, for example, at least one input part 15. At least one input part 15 may be constantly on view.

The user interface means 15, 21 may belong to the equipment 10, for example, for inputting information. Inputting information may be understood very broadly in this context. Besides character input, it can also mean input functions carried out for controlling functions of the equipment 10. These may be, for example, various control signals produced by keys 15. On the other hand, input means may also be understood as, for example, microphone means, whereby the input may be sound, or also in certain situations of interaction, camera devices. In the case according to the embodiment, the user interface means include at least a limited input part 15 known from mobile-station use. In addition, the user interface means may possibly also include an enlarged input part 21. Both input parts 15, 21 may in this case be keyboards suitable for different purposes of use.

The display means of equipment 10 include at least one display 13. The display 13 may be, for example, a so-called multimedia display. It is characteristic of a multimedia display 13 that it can be used to present digital image information, which may have several colours. In addition, the width and height of the multimedia display 13 may be bigger than normal compared with conventional mobile-station display.

In the manner according to the invention, it is possible to use a single display 13, such as, for example, multimedia display 13, in equipment 10 in at least two operating modes of the equipment, for which the display 13 can be arranged in accordance with the method.

In FIG. 1, the equipment 10 according to the invention is shown in its one first operating mode, which in this case is a mobile-station operating mode. In FIG. 2, the equipment 10 is shown in its second operating mode, which in this case is a desktop or a multimedia operating mode. In this case, a desktop operating mode means such a mode especially, where the equipment 10 is to be used for carrying out actions differing from the normal use to make calls or in general the handset use. Examples of this are writing of a text or watching of video clips. On the other hand, such a desktop operating mode does not prevent the traditional use as a mobile station.

When setting the equipment 10 in the desired operating mode, its multimedia display 13 will undergo some acts. With these steps, the structures of the equipment 10, especially the positions of the mono block structure 11 and the multimedia display 13 in relation to one another, are made to correspond with the purpose of the desired operating mode. According to the invention, the equipment 10 may be implemented even by using only one display part 13, which according to the described embodiment is the multimedia display 13, which can be set to function in both operating modes.

Of course, the equipment 10 may also include other display elements or those understood as such. An example of these could be an element, which is located in the side of body structure 11 and which can be used to express the desired information. As examples of such information can be mentioned indication of the state of charge of the battery or the audibility of the mobile station's network or some other corresponding information that is simpler in comparison with multimedia or graphics. For example, the element may be located together with the object according to reference number 22 on the same side of the body of the equipment 10 (not shown).

In its mobile-station operating mode, equipment 10 looks like any mobile telephone. The equipment 10 is hereby used with a limited input part 15, such as a keyboard. The keyboard part 15 may include a digit keyboard of a kind known as such from mobile stations and possibly including navigation/control keys. Also, touchable input parts may also be possible. In addition, the keyboard part 15 may also include keys for management of the multimedia to be presented on display 13. In the mobile-station operating mode, the multimedia display 13 of the equipment 10 is congruent with the body structure 11 of the equipment 10. Display 13 hereby covers at least a part of a possibly enlarged input part 21. In the case according to the embodiment, the enlarged input part 21 is entirely covered by the display 13. The display part 13 is hereby embedded in its place 19 arranged in body structure 11, whereby together with the mono block body 11 of the equipment 10 it forms a fairly smooth, congruent and straightlined structure without any disadvantageous protruding elements or such, which would essentially increase the thickness of the equipment 10.

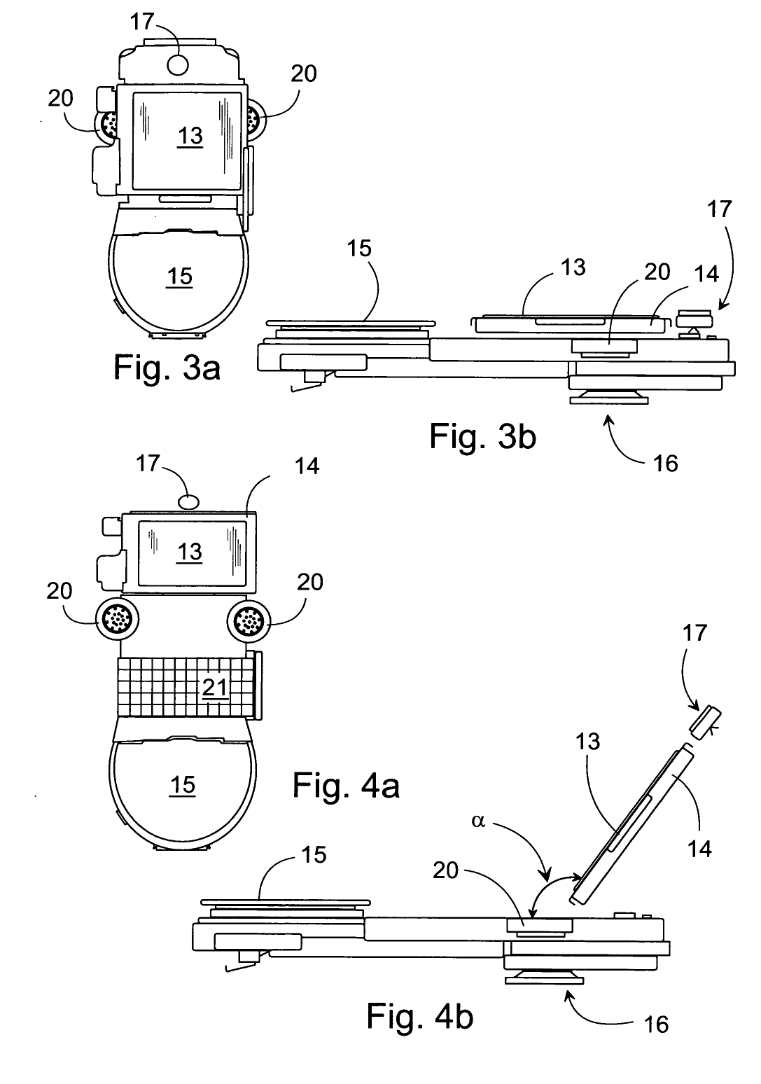

Additional applications may also be located together with multimedia display 13 in the same frame structure 14. A first example of such is an earphone 17 and another example is a digital camera 18 suitable for video negotiation use. The camera 18 is directed to point in the same direction as display 13. Camera 18 may even have simpler properties compared with, for example, a camera sensor 16 located on the backside of the equipment 10 (FIGS. 3b and 4b).

On the side of the body structure 11 of equipment 10, which is opposite to keyboard 15 and multimedia display 13, there may be a possible digital camera 16 (FIGS. 3b and 4b), and when this is used, the multimedia display 13 can be used as a viewfinder.

In the second operating mode of equipment 10 shown in FIG. 2, that is, in this case the so-called multimedia or desktop operating mode, equipment 10 may also be used by using a possible enlarged input part 21. The desktop mode can be turned on by lifting the LCD multimedia display 13 upwards from the body structure 11 of the equipment 10 to some suitable angle α in relation to, for example, the basic body structure 11 of equipment 10, which is placed on a desk or other such plane. After this adjustment the viewing angle α of the display 13 is adapted for the desktop use of the equipment 10. According to one embodiment, display 13 may hereby be stationed in a landscape position (a television-like screen format, landscape).

Some examples ranges for the viewing angle α of the said display 13 relating to the body structure 11 is 80-160 degree. More particular, the suitable viewing angle α of the display 13 relating to the body structure 11 may be somewhat 90-150 degree, for example, 90-130 degrees. By using the definition manner of the viewing angle α presented in Figures, the viewing angle α less than 90 degree might not be so usable in the mean of ergonomic reasons. This is because of the fact that the display 13 begins to “fall” on the input portions 15, 21 in this kind of angle position. Due to this reason the viewing angles α having value 90 degree or more are more suitable. One versed in the art understands that the design of the equipment's 10 body 11 may have effect when defining suitable viewing angle α. Observing that aspect other angle values that may be even outside of the ranges described here in connection may also be possible. In general, the viewing angle α may be adjusted to be such that the display 13 may be viewed rather in front of that like above of that.

In consequence of the lifting operation, the multimedia display 13 is in a vertical position relating to the body 11 and raised from its place 19 arranged in the body structure 11 outside a possible enlarged input part 21.

According to one embodiment, the enlarged input part may include an enlarged keyboard part 21, which is to be regarded as an additional user interface. An example of such is the mini-qwerty-keyboard according to the typewriter standard with possible special keys relating to special functions for the equipment 10 (for example, for multimedia management). A limited input part 15 may also be used simultaneously together with the enlarged input part 21.

Furthermore, the additional user interface may also include loudspeaker devices 20 fitting in a first operating mode of equipment 10 beneath the multimedia display 13 belonging to body structure 11, such as, for example, stereo loudspeakers and/or other access interfaces, for which a place may exist in the body structure 11. According to one embodiment, the loudspeaker devices 20 may form a stereo arrangement, which can be used in order to bring about in a surprising way a stereo sound impression that has so far been lacking in portable multimedia or desktop equipment. The loudspeakers 20 may hereby be located on different sides of the body 11.

The stereo sound system 20 makes possible a mobile-video experience of irreproachable quality, which may either be shared with several observers or which may also alternatively be implemented privately through an earphone connection (not shown).

In transferring to the desktop operating mode, equipment 10 may activate the handsfree facility, either automatically or alternatively through the user's action. In this case, the handsfree facility of equipment 10 may be understood as a use, where the equipment is not held in the hand, hereby also including use of equipment 10 on a desk. In addition, activation may allow, for example, the use of external input devices, such as, for example, bluetooth accessories (for example, a mouse 27 and/or a keyboard 26).

The body structure 11 of equipment 10 may be formed with such a back part that it can be used for supporting the equipment 10 standing in its one operating mode even without any external support. A body structure design of this kind allows using the equipment 10 on a level base, such as, for example, on a desk, in particular. The possibility of using the equipment on a desk is essentially more pleasant from the viewpoint of usability in multimedia applications compared, for example, with having to hold the equipment 10 constantly in the hand. According to one embodiment, the back part of the equipment's body 11 may hereby be essentially planar and in view of the size of the body structure/display size of the equipment 10 may be of a sufficiently wide scope taking into account the dimensions which are decisive for keeping the equipment 10 in a standing position, of which one dimension which can be mentioned as an example is the size of the display part 13 of the equipment 10. On the backside of equipment 10 it is also possible to design (rubber) feet or such elements, on which the equipment 10 may rest steadily and stabile without sliding on a table surface or such flat surface.

In addition to the equipment 10 presented above and the body structure 11 concerning it, the invention also concerns a corresponding method for arranging operating modes of electronic equipment 10 and the use of the equipment in these operating modes. Therein the display means 13 of equipment 10 is arranged for the chosen operating mode. As display means there is now at least one display 13, such as, for example, a multimedia display, which is used in both operating modes to present information.

According to the method, in a first embodiment the equipment 10 is used by using a limited input part 15. Hereby the multimedia display 13 of the equipment 10 is used to cover at least partly a possible enlarged input part 21 of the user interfaces. Hereby the multimedia display 13 will also nearly merge into the body structure 11 of equipment 10. In that case it is in the place 19 arranged for it. In the same way in the second operating mode of equipment 10, it is also possible to operate by using a possible enlarged input part 21. Hereby the multimedia display 13 is supported in a vertical position outside the possible enlarged input part 21. In addition, in the method the display 13 is moved between these at least two operating modes.

Moving of the multimedia display 13 between the first and second operating modes can be done by sliding it in the body structure 11. Thus, the face of the display 13 holds mainly same that will not happen, for example, in claim shell devices. This kind of sliding of the display 13 by using such a hinge arrangement as a turning axis that is not arranged fixedly but sliding allows the mono block implementation for the device 10. Display 13 is hereby in equipment 10 without any fixedly arranged hinge arrangement situated in an essentially fixed manner in body structure 11.

Between the display 13 and the body structure 11 is arranged the sliding hinge arrangement 24. It allows the moving of the display 13 longitudinally in connection with the body structure 11. Body structure 11 and display 13 may have interfitted elements 23, 24 for carrying out the sliding action and non-fixed turning of the display 13. Sliding and thus also the turning of the display 13 between the operating modes are thus carried out not only by turning the display 13 but also moving the display 13 linearly relative to the body structure 11. The linear movement of the display 13 is performed in the elongated direction of the body structure 11. The handset devices have usually the elongated form, which nicely defines this sliding direction.

FIGS. 3a and 4b show the equipment 10 according to the invention as roughly structural application examples in its different operating modes with reference to the reference numbers already mentioned without any body structure surrounding the equipment 10. FIGS. 3b and 4b are cross-sectional views of the equipment 10 in the mobile-station operating mode (FIG. 3b) and in the desktop operating mode (FIG. 4b) respectively. It should be noted that the structures shown in the figures are quite rough and show only by way of example the positions of such components in the equipment 10, which are interesting from the point of view of the invention.

Since the equipment 10 may be implemented even with one display part 13 only, an advantage results from this is the considerably thin appearance of the equipment 10 compared, for example, with state-of-the-art equipment. One structural study at the pilot stage may be mentioned as an example, wherein when embedding the essential components into the setup of the equipment 10 according to the invention on a camera-telephone base conventional as such, the body of equipment 10 was formed thicker by just a few millimetres than a conventional mobile station equipped with camera means, which has no kind of special desk operating mode. In fact, with the arrangement according to the invention a very compact implementation is achieved.

In the following, reference is made to FIGS. 1 and 2 to show an arrangement of a multimedia display 13 in the equipment 10 in the manner according to the invention, very much by way of example and in no way limited by the invention in the light of structural exemplifying features. In display 13 an insert space 19 or other such is arranged in body structure 11, the length and width of which are quite exactly in accordance with the frame structure 14 of the display part 13. When display 13 is in its place 19, it is smoothly congruent with the basic shape of the body structure 11. It is true that a small bulge is possible at the display 13, but in relation to the basic thickness of the body structure 11 of equipment 10 it has only an insignificant effect on the thickness of equipment 10.

The elements 22, 23, 24, 25 belonging to the body structure 11 allow use of the multimedia display 13 in both operating modes and they support the multimedia display 13 in a vertical position outside the enlarged input part 21 in the second operating mode of equipment 10.

As can be seen in FIG. 2, in body 11 of equipment 10 there may be groove guides 23 on both sides of the insert space 19 reserved for the display part 13, which guides run in parallel with the longitudinal direction of the body structure 11. Guides 23 may open towards each other, so that the display part 13 remains in between them when the equipment 10 is in the mobile-station operating mode. Correspondingly, on the down of the frame structure 14 of the display part 13 may have, for example, pins 24 or other such protruding elements, which can be fitted into guides 23 and which move smoothly in the grooves 23 without any considerable clearance. In general, these may be defined to be guide portion 23 or corresponding track or path arranged in connection with the body structure 11 and its counter members 24 arranged in connection with the display element 13, 14. The counter members 24 are more particular in connection with the one end of the display portion 13, 14. The counter members 24 fitted in connection with the guide portion 23 allows besides the turning movement also the sliding movement of the display element 13, 14 between two operating modes.

At chosen places in the grooves 23 there may be, for example, steps or such, to which the pins 24 can be fitted in order to set the desired viewing angle α for the display part 13 without any fixed hinges belonging to body structure 11. Of course, more sophisticated structural solutions are also possible.

The back support of the display part 13 when it is in its desktop position may be arranged, for example, by a support arm arrangement 25 arranged behind it. For example, there may be two arms 25 located on both sides of the display part 13. The first ends of arms 25 may be attached to the frame 14 of display part 13, for example, approximately halfway in the vertical direction. The second ends of arms 25 may be attached in the insert space 19 arranged for the display part 13 and located in the body structure 11 of the equipment 10, for example, on the same line with the groove guides 23. The mounting of both ends of arms 25 may be hinged to allow bending of the arms 25 when the multimedia display 13 is raised and lowered. In addition, in the back part of frame 14 of the display part 13 there may be a space to accommodate the arm 25, into which space the arm 25 will enter when the display part 13 is put in the mobile-station operating mode. In that case the arm 25 is under the display element 13, 14.

To raise and lower the display part 13 several techniques may be applied. Firstly, display part 13 may contain a spring mechanism, so that raising takes place when pushing an activating button 22 for the desktop mode. The button 22 may be located, for example, on a side of body structure 11 of the equipment 10 in the manner shown in FIGS. 1 and 2. Pressing of the button 22 may cause triggering of the mechanical locking of the display part 13, whereby the spring force will make the display 13 spring into its vertical position relative to the body structure 11. The user may then adjust a suitable viewing angle for the display 13, for example, manually by utilising the above-mentioned stepped arrangement. Lowering of the display 13 may be done by hand against the light spring force, whereby when display 13 reaches its position where it merges with the body structure 11 being in the place 19 arranged for it, a locking mechanism connected to button 22 will lock it in its place in space 19 of the body structure 11.

Secondly, raising and lowering of display 13 may also be done entirely by hand. Hereby, for example, there may be a suitably dimensioned recess at the junction of the display part 13 and the body structure 11, such as, for example, at the earpiece 17 end of the equipment 10, to get a good grip on the display part 13 for raising it upwards from body 11.

Thirdly, raising and lowering of the display 13 may also be done electro-mechanically, the various ways of implementation of which are obvious to the professional in the art.

According to one embodiment, display 13 may be connected to the equipment 10 even without the arm mechanism arrangement described above. Hereby moving of the display 13 from one operating mode position to the other may take place, for example, by using a special docking arrangement, in such a way that the display 13 is simply disengaged from its mobile station place 19 in the equipment 10, where it merges with the shape of the body structure 11 of the equipment 10, and it is engaged in the desktop place, where the display part 13 is in a vertical position and at a chosen angle to the basic body structure 11 of the equipment 10. A corresponding action may be used in the opposite case when moving from the desktop operating mode back to the mobile-station operating mode (not shown).

In the case according to this embodiment, the equipment 10 and display 13 may have electronic connector interfaces, where the display 13 can be detachably placed, and the information to be presented on display 13 is conducted and display 13 is controlled through these interfaces.

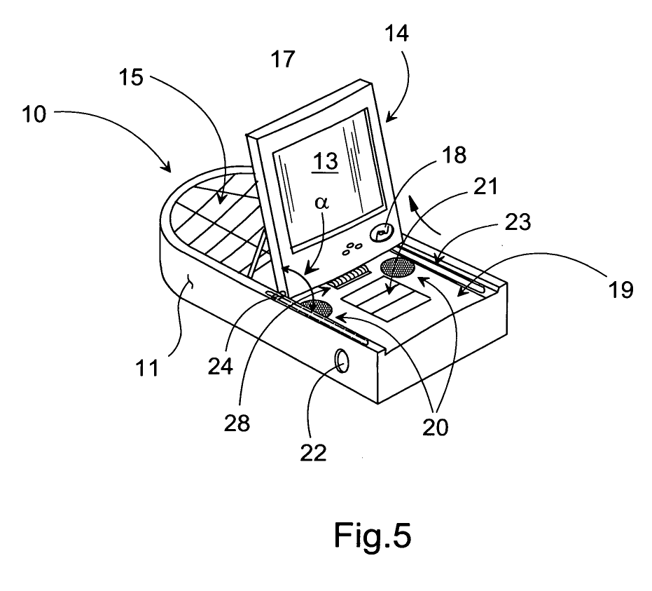

One other alternative for arranging the display 13 in the case both of an arm mechanism described above and also in the case of a docking arrangement, is to use, for example, cabling of the strip type for taking the display control information to the display 13 (an example of a cable is shown in FIG. 5, reference number 28), and due to its very flexible and durable nature it is possible to move the display 13 between the different positions. Besides strip cabling, various cabling and display bus methods are obvious to professionals in the art from the field of mobile stations.

In the embodiment shown in FIGS. 1 and 2, the multimedia display 13 of the equipment 10 can be seen in both operating modes from the same side of the equipment 10. According to another embodiment shown in FIG. 5, the multimedia display 13 may also be arranged in such a way in equipment 10, that in the first operating mode it can be watched in the way now shown in FIG. 1, that is, as from the direction of the equipment's 10 mobile station keyboard 15. In this case, in the second desk-operating mode the display 13 is in fact watched from the direction of the top part of the equipment 10, whereby the mobile station keyboard 15 of the equipment 10 is upside down in relation to the user. The display part 13 may hereby be slided when raising it to the vertical position towards the top edge of the mobile station keyboard 15, for example, with the aid of corresponding mechanism arrangements as in the case according to FIG. 2.

The additional user interface, that is, the mini-qwerty keyboard 21, is now positioned for using the equipment 10 from the direction of its top part. Correspondingly, the camera sensor 18 intended for video-negotiation use is now at the bottom edge of display 13. The embodiment also requires positioning of the information to be presented on display 13 according to each operating mode, that is, according to the position of display 13. This is so because, if information would be presented in a display position according to the mobile-station operating mode even when the equipment 10 is in the desktop operating mode, then the image would be upside down on the display 13. By way of example, FIG. 5 also shows the above-mentioned data-transmission cabling 28 from equipment 10 to display part 13 in the case of a strip-type cabling.

The embodiment described in FIG. 5 allows use of the equipment 10, for example, for giving presentations. The listeners may hereby watch the display 13 from the direction of the top part of the equipment 10 and, correspondingly, the person giving the presentation may be on the side of the equipment's 10 mobile-station keyboard 15, whereby he can control the information shown on the display 13 by using the keyboard 15.

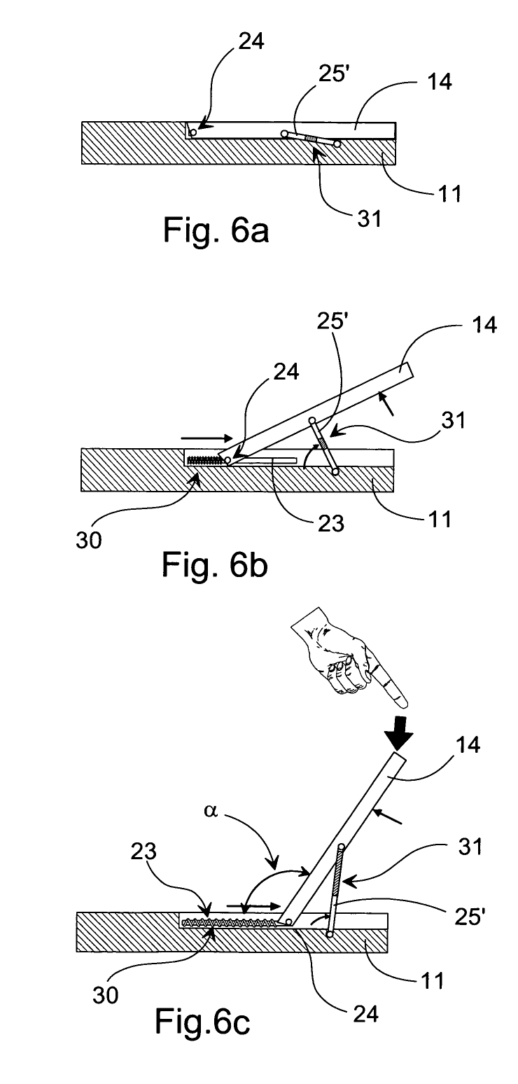

FIGS. 6a-6c present one alternative example for the mechanics of the display 13 support and moving arrangement. In these figures the equipment 10 is observed from side direction. In FIG. 6a the equipment 10 is presented its mobile-station mode in which it may be used as a handset manner and in FIG. 6c in its desktop mode in which that may be away from the user's hand. In FIG. 6b is presented intermediate phase when changing between the operating modes is ongoing.

Here the frame 14 of the display 13 is also equipped with two arms 25′ or corresponding support elements. The arms 25′ have now telescopic construction. At the one end they are hinged to the frame 14 of the display 13 and at their opposite end to the body 11. The hinged fixing point of them at the frame end 14 is near of the middle point of the frame's 14 side. Now also the support arms 25′ of the display 13 are outside of the display 13 in its frame 14. Owing to this kind of fixing the display 13 doesn't increase the length of the equipment 10 when that is adapted to be in its desktop mode. This can be clearly seen from the FIG. 6c.

Now the arms 25′ are also equipped with force elements 31. There may also be force element 30 between the body 11 and the display 13. The force elements 31 may be fitted inside of the support arms 25. One example of this kind of force elements is a spring 30, 31, for example, a coil/helical spring. When the locking mechanism of the display 13 is released, the springs 30, 31 assist to move the display 13 from mobile-station operating mode (FIG. 6a) to the desktop operating mode (FIG. 6c). At the same time the telescopic support arms 25 equipped with spring 31 pushes the display 13 its desktop use position. The design of the arms 25′, springs 30, 31 and guides 23 is arranged to be such that they allow a smooth movement for the display 13 between these two setups.

When the operating mode is changed back to the mobile-station mode from the desktop mode only some force may be needed to push the upper part of the display frame 14 (bold arrow and a hand in FIG. 6c) in order to put the display 13 back to its place 19 in which it merges to the body 11 and allows equipment's handset use. The synchronized movement and precise matching of the above mentioned parts 23, 24, 25′ and also in its part the place of the pivoting points of the support arms 25′ to the body 11 allows for the display 13 a smooth and self-steering movement back to its place 19. The user needs only push lightly the display 13 from its upper part. The described mechanism takes care out the right movement path. This is very important when considering the usability of this kind of two-mode equipment 10. Also, the structure of the turning mechanism is simple. There are no kind of middle pivoting points in the arms 25′ between frame 14 and body 14. Just the pivoting points in connection with them.

The invention has been described above as individual application examples. It should be noted that based on the many examples given in the foregoing, a professional in the art may vary in different ways the presented structural constructions.

It should be understood that the above specification and the figures relating to it are only intended to illustrate the present invention. Thus, the invention is not limited only to the embodiments presented above or to those defined in the claims, but many such different variations and modifications will be obvious to the professional in the art, which are possible within the scope of the inventive idea defined by the appended claims.

1. Electronic equipment including
a body structure in which a place is arranged for at least one display and belonging in connection with the body structure
display means including at least one said display, whereby the said display allows use of the equipment in at least two operating modes, and
user interface means for inputting information to the equipment and including at least one input part being constantly on view, and which equipment and especially its at least one said display can be adapted to at least two operating modes for presenting the information, of which
in the first operating mode, being the mobile-station operating mode, the said display is adapted to merge with the body structure of the equipment being in the place arranged for it, and
in the second operating mode, the display is raised from its place, and in both operating modes information is adapted to be inputted to the equipment by the user interface means,
characterized in that the second operating mode is a desktop operating mode in which the viewing angle (α) of the display is adapted for the desktop use of the equipment.

2. Equipment according to claim 1, characterized in that the said viewing angle (α) of the said display relating to the body structure is 80-160 degree.

3. Equipment according to claim 2, characterized in that the said viewing angle (α) of the display relating to the body structure is somewhat 90-150 degree.

4. Equipment according to claim 1, characterized in that between the said display and body structure a hinge arrangement is arranged that is arranged to move the display longitudinally in connection with the body structure.

5. Equipment according to claim 4, characterized in that hinge arrangement includes guides arranged in connection with the body structure and counter members arranged in connection with the said display and arranged to be moved in the guides.

6. Equipment according to any claim 1, characterized in that the user interface means also include an enlarged input part, which is adapted to be covered at least in part under the said display in the mobile-station operating mode of the equipment.

7. Equipment according to any claim 1, characterized in that in the body structure are arranged loudspeaker devices, which are covered under the said display in the mobile-station operating mode of the equipment.

8. Equipment according to claim 7, characterized in that the loudspeaker devices are adapted to form a stereo arrangement.

9. Equipment according to claim 1, characterized in that external user interface devices may be adapted in the equipment, such as, for example, a keyboard part or a mouse control.

10. Equipment according to claim 1, characterized in that the body structure of the equipment is adapted to keep the equipment in a stabile position in the desktop operating mode, especially for its handsfree use.

11. Method for using electronic equipment, wherein the electronic equipment is formed by a body structure including display means and user interface means in which body structure is arranged a place for at least one display, while the display means include at least one said display and the user interface means include at least one input part being constantly on view, and which equipment and especially its at least one said display can be arrange at least two operating mode, in which
in the first operating mode being a mobile-station operating mode, the said display merges with the body structure of the equipment being in the place arranged for it, and
in the second operating mode, the said display is raised from its place, and in both operating modes information is adapted to be inputted to the equipment by the user interface means and information is presented on the said display, characterized in that the second operating mode is a desktop operating mode in which the viewing angle (α) of the display may be adapted for the desktop use of the equipment.

12. Method according to claim 11, characterized in that the said viewing angle (α) of the said display relating to the body structure is 80-160 degree.

13. Method according to claim 12, characterized in that the said viewing angle (α) of the display relating to the body structure is somewhat 90-150 degree.

14. Method according to claim 11, characterized in that between the said display and body structure a hinge arrangement is arranged by means of which the display is moved longitudinally in connection with the body structure when changing the operating mode.

15. Method according to claim 14, characterized in that the said display is moved between the first and second operating modes by sliding it in the body structure.

16. Body structure of electronic equipment, where the following can be fitted in connection with the body structure
display means, including at least one display for which a place is arranged in the body structure, and
user interface means, including at least one input part being constantly on view, and
which at least one said display can be adapted into at least two operating modes for presenting the information, of which
in the first operating mode, being the mobile-station operating mode, the said display is adapted to merge into the body structure being in the place arranged for it, and
in the second operating mode, the said display is raised from its place, and in both operating modes information is adapted to be inputted to the equipment by the user interface means and in the body structure elements are fitted to allow use of the said display in both operating modes to present information, characterized in that, the second operating mode is a desktop operating mode for which elements are fitted to the body structure in order to allow use of the said display in the said desktop operating mode.

17. Body structure according to claim 16, characterized in that elements are fitted to arrange between the said display and body structure a hinge arrangement that is arranged to move the said display longitudinally in connection with the body structure.

18. Body structure according to claim 17, characterized in that hinge arrangement includes guides arranged in connection with the body structure and to which guides counter members arranged in connection with the said display may be fitted.

19. Body structure according to claim 16, characterized in that the user interface means fitted into the body structure also include an enlarged input part, which is adapted to be covered at least partly under the said display in the mobile-station operating mode of the equipment.

20. Body structure according to claim 16, characterized in that the body structure of the equipment is adapted to keep the equipment in a stabile position in the desktop operating mode, especially for its handsfree use.

21. Body structure according to any claim 16, characterized in that the body structure includes elements for adjusting the viewing angle (α) of the display.
